(19) United States
(12) Patent Application Publication
(10) Pub. No.: US 2026/0304919 A1
(43) Pub. Date: Oct. 1, 2026

(54) MONOLITHIC INTEGRATION OF III-N DEVICES INCLUDING A CONDUCTIVE LAYER

(71) Applicant: TEXAS INSTRUMENTS INCORPORATED, Dallas, TX (US)

(72) Inventor: Dong Seup Lee, Allen, TX (US)

(21) Appl. No.: 19/096,024

(22) Filed: Mar. 31, 2025

(51) Int. Cl. H10D 84/82; H10D 62/85; H10D 62/852

(52) U.S. Cl. CPC H10D 84/82; H10D 62/8503; H10D 62/852

(57) ABSTRACT

A monolithic III-N semiconductor device including a half-bridge circuit is disclosed. In one example, the semiconductor device comprises a first III-N field effect transistor (FET) including a first gate, the first III-N FET disposed between an output node and a reference voltage node; a second III-N FET including a second gate, the second III-N FET disposed between an input voltage node and the output node; and a third III-N FET including a third gate connected to the second gate, the third III-N FET disposed between the input voltage node and a node internal to the second III-N FET.

### FIELD OF THE DISCLOSURE

Disclosed implementations relate generally to the field of group III-N semiconductor devices and their fabrication.

### BACKGROUND

Group III nitride materials (also referred to as III-N materials) possess a unique combination of physical and electrical properties found to be beneficial in modern microelectronics and optoelectronics. Among these properties are wide bandgap, high saturated drift velocity and breakdown voltage, high thermal conductivity, robust chemical and thermal stability, etc. Due to these characteristics, III-N materials are being considered as promising materials for fabrication of powerful high-frequency transistors capable of functioning at high temperatures and in hostile environments. Whereas advances in III-N devices and their fabrication continue to grow apace, several lacunae remain, thereby requiring further innovation as will be set forth hereinbelow.

### SUMMARY

The following presents a simplified summary in order to provide a basic understanding of some examples of the present disclosure. This summary is not an extensive overview of the examples, and is neither intended to identify key or critical elements of the examples, nor to delineate the scope thereof. Rather, the primary purpose of the summary is to present some concepts of the present disclosure in a simplified form as a prelude to a more detailed description that is presented in subsequent sections further below.

In one example, a semiconductor device is disclosed. The semiconductor device comprises a substrate; a lower III-N stack over the substrate; a conductive layer over the lower III-N stack; an upper III-N stack over the conductive layer, the upper III-N stack including a channel layer; and a barrier layer over the channel layer, where the barrier layer and the channel layer may form a first heterojunction structure. The semiconductor device further comprises a first III-N transistor disposed in or over a first area of the substrate, the first III-N transistor including a first source region and a first drain region, where a first drain contact is disposed in the first drain region and a first source contact is disposed in the first source region; a second III-N transistor disposed in or over a second area of the substrate, the second area laterally separated from the first area by a first isolation region, the second III-N transistor including a second source region and a second drain region, where a second drain contact is disposed in the second drain region and a second source contact disposed in the second source region is connected to the first drain contact of the first III-N transistor; and a third III-N transistor disposed in or over a third area of the substrate, the third area laterally separated from the second area by a second isolation region, the third III-N transistor including a third source region and a third drain region, where a third source contact disposed in the third source region is coupled to the conductive layer and a third drain contact disposed in the third drain region is connected to the second drain contact of the second III-N transistor, and where a third gate contact of the third III-N transistor is connected to a second gate contact of the second III-N transistor.

In one example, a semiconductor device is disclosed. The semiconductor device comprises a first III-N field effect transistor (FET) including a first gate, the first III-N FET disposed between an output node and a reference voltage node; a second III-N FET including a second gate, the second III-N FET disposed between an input voltage node and the output node; and a third III-N FET including a third gate connected to the second gate, the third III-N FET disposed between the input voltage node and a node internal to the second III-N FET.

In one example, a method of fabricating a semiconductor device is disclosed. The method comprises forming a lower III-N stack over a substrate; forming a conductive layer over the lower III-N stack; forming an upper III-N stack over the conductive layer, the upper III-N stack including a channel layer; forming a barrier layer over the channel layer, the barrier layer and the channel layer forming a first heterojunction structure; forming a first III-N transistor in or over a first area of the substrate; forming a second III-N transistor in or over a second area of the substrate; forming a third III-N transistor in or over a third area of the substrate, where a source of the third III-N transistor is coupled to the conductive layer; connecting a source of the second III-N transistor to a drain of the first III-N transistor; connecting a drain of the second III-N transistor to a drain of the third III-N transistor; and connecting a gate of the second III-N transistor to a gate of the third III-N transistor.

### BRIEF DESCRIPTION OF THE DRAWINGS

Implementations of the present disclosure are illustrated by way of example, and not by way of limitation, in the Figures of the accompanying drawings. Different references to “an” or “one” implementation in this disclosure are not necessarily to the same implementation, and such references may mean at least one. Further, when a particular feature, structure, or characteristic is described in connection with an implementation, such feature, structure, or characteristic in connection with other implementations may be feasible whether or not explicitly described.

The accompanying drawings are incorporated into and form a part of the specification to illustrate one or more example implementations of the present disclosure. Various advantages and features of the disclosure are described in the following Detailed Description taken in connection with the appended claims and with reference to the attached drawing Figures in which:

FIG. 1 depicts a cross-sectional view of a semiconductor device including a conductive layer according to an example;

FIG. 2 depicts a cross-sectional view of a semiconductor device including a conductive layer according to another example;

FIG. 3 depicts a cross-sectional view of a semiconductor device including a conductive layer according to another example;

FIG. 4 depicts a schematic of a half-bridge circuit representative of a semiconductor device according to an example; and

FIG. 5 is a flowchart of a method of fabricating a semiconductor device according to some examples of the present disclosure.

### DETAILED DESCRIPTION

Examples of the disclosure are described with reference to the attached Figures where like reference numerals are generally utilized to refer to like elements. The Figures are not drawn to scale and they are provided merely to illustrate examples. Numerous specific details, relationships, and methods are set forth below to provide an understanding of one or more examples. However, some examples may be practiced without such specific details. In other instances, well-known subsystems, components, structures and techniques have not been shown in detail in order not to obscure the understanding of the examples. Accordingly, the examples of the present disclosure may be practiced without such specific components.

Additionally, terms such as “coupled” and “connected,” along with their derivatives, may be used in the following description, claims, or both. These terms are not necessarily intended as synonyms for each other. “Coupled” may be used to indicate that two or more elements, which may or may not be in direct physical or electrical contact with each other, co-operate or interact with each other. “Connected” may be used to indicate the establishment of communication, i.e., a communicative relationship, between two or more elements that are coupled with each other.

Without limitation, examples of the present disclosure will be set forth below in the context of improving performance characteristics of semiconductor devices based on Group III nitride materials, also referred to as III-N materials, such as gallium nitride (GaN) devices.

GaN devices, e.g., GaN field effect transistors (FETs), provide certain performance advantages over silicon, including lower on-state resistance (e.g., drain-source resistance or R_{DSON}), lower switching losses, and improved breakdown voltage, among others. GaN transistors include a hetero epitaxy structure with a junction between materials of different bandgaps (e.g., a heterojunction structure), such as aluminum gallium nitride (AlGaN) and gallium nitride, to provide a 2-dimensional electron gas (2DEG) formed within the AlGaN/GaN hetero epitaxy structure that is used for device operation—e.g., forming a channel of the GaN device. The 2-dimensional electron gas (2DEG) may be referred to as a 2DEG channel. Depletion mode (DMODE) GaN transistors are normally on, whereas enhancement mode (EMODE) GaN transistors are normally off. In some examples, EMODE GaN transistors include a gate stack with a gallium nitride (p-GaN) layer including p-type dopants, such as magnesium (Mg) or other p-type dopants. When the p-type dopants are activated, the p-GaN layer may deplete the 2DEG beneath the gate stack at zero or negative gate bias. Applying a positive gate voltage enhances the 2DEG under the gate and turns the EMODE GaN device on to allow current flow between the source and drain.

In some examples, a GaN device may be formed with one or more III-N layers (e.g., AlGaN layer, GaN layer, AlN layer, etc.) epitaxially grown (which may be referred to as a III-N epi stack or III-N stack) over a suitable semiconductor substrate, e.g., including a silicon substrate. A portion of the III-N layers (e.g., AlGaN layer formed on GaN layer) may form a heterojunction structure over a III-N buffer stack of the semiconductor substrate. In some implementations, a p-GaN layer may be provided over the heterojunction structure for effectuating EMODE device functionality. The p-GaN layer may have a suitable thickness and include appropriate levels of p-type dopants to control the threshold voltage (V_{T} or V_{TH}) and manage R_{DSON} performance of the GaN device. In general, higher threshold voltages are desired in order to reduce the likelihood of accidentally turning on an EMODE device, increase operational margins, reduce leakage current (e.g., off-state I_{DS}), etc.

Due to their well-recognized advantages, development efforts are underway to incorporate GaN FETs into a variety of applications. For example, some of the widespread applications include switched-mode power supply (SMPS) applications capable of handling voltages ranging up to several hundreds or even thousands of volts. Further, monolithic integration of GaN FETs (e.g., fabrication of multiple FETs in or over a common substrate) is also being actively pursued to maximize the advantages of GaN FETs by increasing switching frequencies with lower parasitic inductances (e.g., inductance due to bond wire connections between semiconductor dies). Moreover, monolithic integration may provide die size benefits by reducing overall circuit area in certain implementations.

In some example power supply applications, a half-bridge circuit configuration may be used for outputting a bias voltage (e.g., a high rail voltage) according to a control scheme. In such configurations, a switching node is alternately switchable to a first voltage (e.g., a high voltage or a rail voltage) and a second voltage (e.g., a low voltage or a reference voltage) using an arrangement of GaN FET switches that may be disposed in two separate voltage domains. For example, a first GaN FET may be disposed in a low voltage domain of the half-bridge circuit and a second GaN FET may be disposed in a high voltage domain of the half-bridge circuit. In some implementations, the low voltage domain may be referred to as a “low side” and the GaN FET disposed therein may be referred to as a low side FET or LSFET. Likewise, the high voltage domain may be referred to as a “high side” and the GaN FET disposed therein may be referred to as a high side FET or HSFET. It may be desirable to integrate both HSFET and LSFET devices on the same substrate in certain implementations of a half-bridge circuit so as to benefit from the aforementioned advantages.

Although the advantages of monolithic integration of GaN FETs are compelling, several challenges remain. For example, because there are no structures in a GaN stack that are analogous to P/N-wells used in CMOS integration, having a common substrate in a half-bridge circuit configuration can give rise to what is referred to as back gating. Back gating in a GaN semiconductor device may be caused due to a voltage difference between a device node coupled to the high voltage and the substrate that is coupled to the low voltage (e.g., a ground node). When there is a sufficient potential difference between a high voltage node and the substrate during device operation, the potential difference may exert a downward electric field (E-field) on the conductive channel (e.g., a 2DEG or 2-dimensional hole gas (2DHG)). In certain operating conditions, the downward E-field may cause a depletion (or reduction) of the mobile charges in the conductive channel, which can lead to various undesirable consequences. For example, R_{DSON} of the device may be increased when the device deployed in a power supply application is turned on. Accordingly, overall device performance may be impacted due to back gating in such scenarios.

In some example solutions to mitigate back gating in a monolithic half-bridge design, a doped GaN or AlGaN layer is inserted in the buffer layer of a III-N epi stack. The doped GaN or AlGaN layer forms a conductive layer providing a conductive sheath between 2-dimensional conductive channel and the substrate. As such, the doped GaN or AlGaN layer is operable as a virtual substrate to which a source of the HSFET may be coupled (in addition to the source coupled to a source region of the HSFET device). Because of the virtual substrate interposed in the III-N epi stack, back gating effect due to the voltage differential between a high voltage device node, e.g., the drain of the HSFET, and the substrate may be mitigated—e.g., at least partially screened or blocked. Accordingly, such a conductive layer may be referred to as a screening layer.

In another example solution, an auxiliary heterojunction structure may be formed (or inserted) in the buffer layer of a III-N epi stack. Such a heterojunction structure is operable to support a second channel for mobile charges, e.g., electrons in a 2DEG or holes in a 2DHG, in the buffer layer, hence forming a conductive layer in the III-N epi stack. Similar to the inserted doped layer described above, the auxiliary heterojunction structure is operable as a virtual substrate in this arrangement. Accordingly, the effect of back gating may be mitigated in such arrangement in a similar manner.

Whereas the foregoing solutions may reduce back gating in a monolithic half-bridge GaN circuit design, certain deficiencies and shortcomings remain. For example, when the HSFET device is turned on, the virtual substrate in the high side portion may be pulled high (e.g., close to a high voltage or a rail voltage). Accordingly, full input voltage (e.g., a rail voltage) to the monolithic half-bridge GaN circuit needs to be blocked between the virtual substrate, e.g., the doped GaN/AlGaN layer or the auxiliary heterojunction structure, and the silicon substrate that is at a reference voltage (e.g., ground). On the other hand, when the HSFET device is turned off and the LSFET device is turned on, the virtual substrate in the high side portion may be pulled low (e.g., close to a low voltage, a reference voltage) in some examples having the virtual substrate common (e.g., connected) between the drain of LSFET and the source of HSFET devices. Accordingly, the full input voltage needs to be blocked between the high voltage drain of the HSFET device and the virtual substrate. As the monolithic half-bridge circuit requires full swing voltage blocking capability across two different vertical portions of the III-N epi stack depending on the on/off states of the HSFET device, overall thickness of the III-N epi stack needs to be about two times thicker than the thickness required for a target input voltage (V_{IN}) specified for the circuit. However, manufacturing relatively thicker stacks increases process cost and presents technical challenges such as wafer bow and stress control during fabrication.

Examples of the present disclosure recognize the foregoing challenges and advantageously provide solutions for mitigating the effect of back gating in a monolithic half-bridge GaN circuit design. In some arrangements, a conductive layer operable as a virtual substrate (VS) is inserted at a suitable depth in a III-N buffer stack for blocking (or reducing) the effects of back gating in a HSFET of the circuit. In some arrangements, the potential of the virtual substrate is controlled by a separate GaN FET (referred to as a VSFET) provided in the high side portion of a half-bridge circuit where a source of the VSFET is connected to the virtual substrate such that the virtual substrate may be selectively pulled high (e.g., close to a high voltage or a rail voltage) only during certain phases of device operation.

In an example implementation, when the HSFET is off, the VSFET is also off, thus causing the virtual substrate to float while being capacitively coupled to the HSFET's drain on one side and the substrate on the other side. Accordingly, an input voltage (V_{IN}) coupled to the HSFET's drain may be blocked using the entire III-N epi stack rather than just a portion of the III-N epi stack. In this manner, the need for a separate—and additional—portion of the III-N epi stack to withstand and block the input voltage is obviated. As a result, relatively thinner III-N epi stacks (e.g., having a thickness less than twice the thickness needed for a given voltage rating in some implementations) may be provided to support the input voltage according to some examples of the present disclosure. Because the manufacture of thinner stacks is more economical, cost savings may also be realized in some examples. Whereas the examples herein may provide various structures, materials and processes that may engender these and other beneficial effects, no particular result is a requirement unless explicitly recited in a particular claim.

According to the examples herein, a semiconductor device of the present disclosure is representative of a III-N half-bridge circuit in a monolithic implementation that may be deployed in various applications—e.g., power supply applications. In some arrangements, the semiconductor device may include a suitable substrate and a heterojunction structure formed over a III-N buffer stack that extends across the substrate. The semiconductor device may include a conductive layer disposed at a suitable depth in the buffer stack, e.g., over a lower III-N stack comprising one or more buffer layers formed over the substrate. In some examples, the conductive layer may have free charge carriers and may be arranged to operate as a virtual substrate that is selectively driven (e.g., floating) in operation of the semiconductor device. The semiconductor device may include an upper III-N stack formed over the conductive layer. A channel layer of the upper III-N stack is operable in conjunction with a barrier layer as part of a heterojunction structure to support a conductive channel of the semiconductor device, e.g., a 2DEG channel.

A III-N half-bridge circuit in accordance with the present disclosure includes a low side (LS) FET, a high side (HS) FET and a virtual substrate (VS) switching FET (VSFET) coupled to the HSFET, where the LSFET, HSFET and VSFET devices may be formed in different areas of the substrate. For purposes herein, the conductive layer may also be referred to as a screen layer, VS layer, or simply “VS” in some examples. The conductive layer is switchably connectable to an input voltage (e.g., a high voltage, a rail voltage) connected to a node of the HSFET (e.g., a drain of the HSFET) by turning on the VSFET. In some examples, the conductive layer may be operable as an internal node of the high side FET (e.g., virtual substrate node). During operation of the semiconductor device, the conductive layer is pulled high when the HSFET and the VSFET are on. Accordingly, the potential difference between the 2DEG channel and the conductive layer is minimized or eliminated in the HSFET. As such, the conductive layer is operable, when pulled high, to shield the 2DEG channel from the electric field that would have developed between the 2DEG channel and a reference potential (e.g., a ground) associated with the substrate. In this manner, the back gating effect on the HSFET when the HSFET is on is minimized or reduced, thus advantageously improving R_{DSON} performance of the HSFET.

Furthermore, because the potential difference between the 2DEG channel and the conductive layer is minimal when the VSFET and HSFET devices are turned on, the upper III-N stack does not need to be a thick structure of III-N semiconductor material. Consequently, the upper III-N stack may have a thickness that is only a small portion (e.g., less than 10% in some examples) of the thickness of the III-N stack.

When the HSFET is off and the LSFET is on, the VSFET is turned off. As such, the potential on the conductive layer is indeterminate, e.g., “floating”, as the conductive layer is disconnected from the high voltage input node (e.g., drain of HSFET). Consequently, the potential difference between the drain of the HSFET connected to the high voltage input node and the substrate needs to be blocked by the entire III-N stack, including the lower III-N stack. The semiconductor device according to some examples herein may therefore comprise a lower III-N stack having a sufficient thickness that forms a substantial portion of the III-N stack in order to facilitate blocking of the potential difference when the HSFET is off. In some arrangements, the lower III-N stack may have a thickness of about greater than 90% of the total thickness of the III-N stack. Because the semiconductor device may be fabricated to have a thinner upper III-N stack while maintaining blocking capability to withstand the electrical fields that may be developed in high voltage applications, the examples herein may advantageously overcome the deficiencies of the half-bridge circuit designs set forth above—e.g., having a total thickness of III-N stack being approximately twice that of a III-N stack required for a given voltage rating.

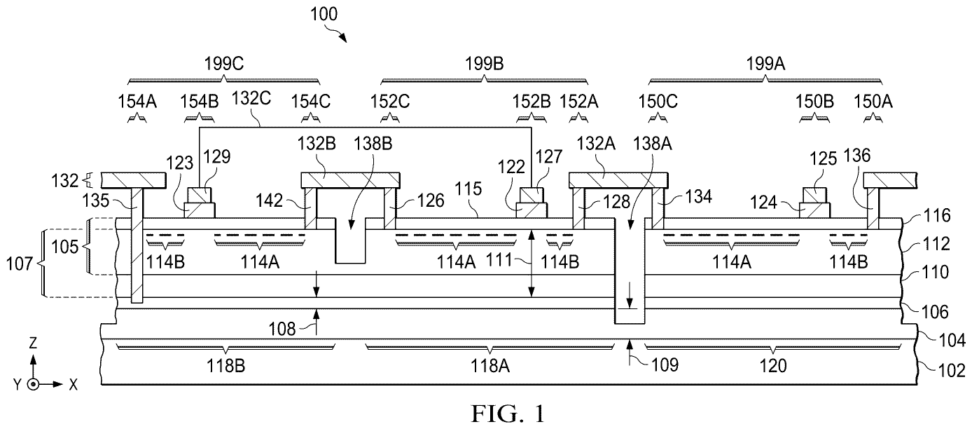

Turning to the Figures, FIG. 1 depicts a cross-sectional view of a semiconductor device 100 including a conductive layer operable as a selectively driven virtual substrate according to an example. The semiconductor device 100 may include a suitable substrate 102, which may be provided as a silicon wafer, a silicon-on-sapphire wafer, or a silicon carbide wafer, and/or as a semiconductor substrate including cores with matching coefficient of thermal expansion (CTE), and/or the like. In one arrangement, the substrate 102 may comprise monocrystalline silicon having a (111) crystal orientation in order to facilitate epitaxial growth of III-N semiconductor material.

The semiconductor device 100 includes a lower III-N stack 104 comprising one or more buffer layers or sublayers of III-N semiconductor material over the substrate 102. For purposes herein, the lower III-N stack 104 is depicted in FIG. 1 as a single layer, which may also be referred to as a lower buffer layer or lower buffer portion without limitation. The lower III-N stack 104 may include a nucleation sublayer, not specifically shown, of aluminum nitride (AlN) on the substrate 102. In an example implementation, the AlN sublayer may have a lattice constant close to silicon's lattice constant, which may advantageously enable epitaxial growth of a low defect III-N semiconductor material on the substrate 102. Furthermore, the lower III-N stack 104 may include one or more transition sublayers, not specifically shown, of aluminum gallium nitride (AlGaN) with increasing gallium content, extending over the nucleation sublayer. The lower III-N stack 104 may have a thickness 109, e.g., around 1 micron (μm) to 10 μm, depending on operating voltage levels of an application environment in which the semiconductor device 100 may be deployed. Other structures and compositions for the lower III-N stack 104 are within the scope of this example.

The semiconductor device 100 includes a conductive layer 106 of III-N semiconductor material over the lower III-N stack 104. As will be set forth below, the conductive layer 106 is operable as an internal VS node selectively driven for mitigating the effects of back gating in the semiconductor device 100. In one example, the III-N semiconductor material of the conductive layer 106 is doped with dopants having a first conductivity type. Accordingly, the conductive layer 106 includes free carriers, also referred to as mobile carriers or mobile charges, and has the first conductivity type. In one implementation, the III-N semiconductor material of the conductive layer 106 may comprise primarily of GaN material and the dopants. In one version of this example, the first conductivity type may be p-type such that the free carriers are holes, and the first conductivity type dopants may include magnesium (Mg). In another version of this example, the dopants may have a second conductivity type, e.g., n-type, where the free carriers are electrons, and may include silicon (Si) or germanium (Ge). Other dopants for the conductive layer 106 are within the scope of this example.

In some implementations, an average dopant density in the conductive layer 106 may be 1×10¹⁶ cm⁻³ to 5×10²¹ cm⁻³, by way of example. During operation of the semiconductor device 100, the conductive layer 106 may be partially depleted due to a potential difference between the substrate 102 and a 2DEG channel (e.g., 2DEG 114) above the conductive layer 106. A thickness 108 of the conductive layer 106 may be provided to be sufficiently large so that a portion of the free carriers remain in the conductive layer 106 when the conductive layer 106 is partially depleted. The thickness 108 may be 10 nanometers (nm) to 1 μm or more, by way of example. In one arrangement, the conductive layer 106 may extend over and across the lower III-N stack 104 except where discontinuities are caused by suitable isolation regions, e.g., isolation regions 138A, as will be set forth further below. Accordingly, the conductive layer 106 may comprise multiple segments overlying the lower III-N stack 104, where the segments may operate as internal nodes with respect to the corresponding GaN transistors formed as part of the semiconductor device 100. Furthermore, depending on how the GaN transistors are interconnected, respective internal nodes may have different voltages at different phases of device operation.

The semiconductor device 100 includes an upper III-N stack 107 disposed over the conductive layer 106, where the upper III-N stack 107 may have a thickness 111 substantially smaller than the thickness 109 of the lower III-N stack 104. In one arrangement, the upper III-N stack 107 may include an upper buffer layer 110 over the conductive layer 106. Where provided, the upper buffer layer 110 may also be referred to as an upper buffer portion in some examples. In some versions of this example, the upper buffer layer 110 may be 100 nm to 5 μm thick, for example, and may provide a transition from the conductive layer 106 to active components (e.g., including a conductive channel) in the semiconductor device 100.

The upper III-N stack 107 of the semiconductor device 100 includes an unintentionally doped (UID) layer 112 of III-N semiconductor material operable to support a 2DEG 114 in association with a barrier layer 116. As such, the UID layer 112 may be referred to as a channel layer 112. The UID layer 112 may comprise undoped GaN material in some examples. In various examples, the concentration of dopant(s) in the UID layer 112 may not be detectable, and the UID layer may also be referred to as an undoped layer 112. In some examples, the UID layer 112 (or undoped layer 112) includes carbon concentration in the order of about 1×10¹⁵ cm⁻³ or about 1×10¹⁶ cm⁻³. In some examples, the UID layer 112 may include iron (Fe), silicon (Si) and/or magnesium (Mg). In some examples, the UID layer 112 (or undoped layer 112) is free of (exclusive of) aluminum. In some examples, a channel layer 112 may be regarded as formed over the upper buffer layer 110—e.g., over a top portion of the buffer layer 110, as depicted in FIG. 1. In some examples, a channel layer 112 may be regarded as part of the upper buffer layer 110.

The barrier layer 116 and the channel layer 112 may form a heterojunction structure 105. The barrier layer 116 may comprise suitable III-N semiconductor material and extend over the channel layer 112. The barrier layer 116 may be substantially homogeneous and include primarily AlN, AlGaN, or other III-N semiconductor material having a higher bandgap energy than the channel layer 112. Alternatively, the barrier layer 116 may include sublayers of different compositions, such as a sublayer of AlN on the channel layer 112 and a sublayer of AlGaN over the AlN sublayer (not shown in FIG. 1).

In some examples, the barrier layer 116 may have a thickness ranging from about 1 nanometer (nm) to about 60 nm, and may include aluminum and nitrogen. In some versions of this example, the barrier layer 116 may include gallium at a lower atomic percent than aluminum. In some versions of this example, the barrier layer 116 may include gallium at a higher atomic percent than aluminum. In some versions, the barrier layer 116 may also include indium (e.g., as InAlGaN material). In some examples, the barrier layer 116 includes an AlGaN layer.

Whereas a channel layer (e.g., channel layer 112) may primarily include GaN material, there may be optional trace amounts of other group III elements, such as aluminum or indium, in some implementations. The barrier layer 116 over the channel layer 112 is operable as part of the heterojunction structure 105 for causing the formation of a 2DEG, e.g., 2DEG 114, in the channel layer 112 proximate to an interface between the barrier layer 116 and the channel layer 112.

Depending on implementation and application environment, an epi stack of suitable thickness including the lower III-N stack 104, conductive layer 106 and the upper III-N stack 107 may be formed over the substrate 102. In some arrangements, the epi stack may have an overall thickness ranging from about 2 μm to about 15 μm. In some arrangements, the conductive layer 106 may be provided at a depth from a surface 115 (e.g., a top surface) of the barrier layer 116, which may be primarily determined by the thickness 111 of the upper III-N stack 107. In some arrangements, a thickness of the upper III-N stack 107 may in turn be determined by a thickness of the upper buffer layer 110 if included. Regardless of whether an upper buffer layer is present, the conductive layer 106 may be at a depth of about 400 nm to 800 nm from the surface 115 in some arrangements.

Further, a composition and thickness of the barrier layer 116 may be selected to provide a desired electron density in the 2DEG 114. The 2DEG 114 may have an electron density of 1×10¹² cm⁻² to 1×10¹⁵ cm⁻², by way of example. The 2DEG 114 may extend across the heterojunction structure 105 except where isolation regions 138A, 138B are provided to demarcate active regions of different GaN FETs formed in or over the corresponding areas of the heterojunction structure 105 as will be set forth below. In addition, the 2DEG 114 may be depleted in the gate regions of respective GaN FET devices to effectuate EMODE functionality (i.e., normally off mode). In this manner, the 2DEG 114 in a GaN FET may be established as a conductive channel having two segments 114A and 114B that may be electrically connected when the GaN FET is turned on.

As illustrated, the semiconductor device 100 includes a half-bridge stage comprising an LSFET 120 formed in a first area 199A, an HSFET 118A formed in a second area 199B, and a VSFET 118B formed in a third area 199C of the substrate 102. For purposes of some examples herein, LSFET 120 may be referred to as a first III-N transistor or first GaN FET, HSFET 118A may be referred to as a second III-N transistor or second GaN FET, and VSFET 118B may be referred to as a third III-N transistor or third GaN FET. To effectuate transistor functionality, each GaN FET includes respective source, drain and gate regions. Although not specifically referred to in FIG. 1, each GaN FET may also include a source access region laterally extending between the gate region and the source region as well as a drain access region between the gate region and the drain region, respectively.

By way of illustration, LSFET 120 includes a first source region 150A, a first drain region 150C and a first gate region 150B of the first area 199A. Likewise, HSFET 118A includes a second source region 152A, a second drain region 152C and a second gate region 152B of the second area 199B that is laterally spaced apart from the first area 199A by a first isolation region 138A. Further, VSFET 118B includes a third source region 154A, a third drain region 154C and a third gate region 154B of the third area 199C that is laterally spaced apart from the second area 199B by a second isolation region 138B.

In an example implementation of the semiconductor device 100, each GaN FET may comprise an EMODE device. Accordingly, a p-doped III-N layer, e.g., comprising one or more layers of III-N material, is patterned over the barrier layer 116 in the gate regions 150B, 152B, 154B of GaN FETs 120, 118A, 118B, respectively, to form a gate as part of rspective gate stacks of the GaN FET devices. In some examples, the p-doped III-N layer may also be referred to as a p-III-N layer or a p-GaN layer. The formation of the p-GaN layer causes the 2DEG to be reduced—e.g., absent, in some cases. In versions of this example, the p-doped III-N layer may comprise a GaN layer doped with Mg or other p-type dopants. In some examples, the p-doped GaN layer may include a p-dopant concentration of about 1×10¹⁷ atoms/cm³ to 1×10²¹ atoms/cm³ and may have a thickness of about 10 nm to 200 nm. In some additional and/or alterative arrangements, additional layers such as an AlGaN cap layer of about 4 nm to 10 nm (e.g., devoid of p-doping) and/or a low-pressure chemical vapor deposition (LPCVD) silicon nitride (SiN) cap layer of about 10 nm to 20 nm, which are not specifically shown in the Figures, may be optionally provided over the p-GaN layer before patterning a gate.

As a result of patterning the p-GaN layer, e.g., by removing portions of the p-GaN layer outside the gate region of each GaN FET, a gate (e.g., a p-GaN gate) is formed over the barrier layer 116 in respective gate regions of the corresponding GaN FET devices. Accordingly, a first gate 124, a second gate 122, and a third gate 123 are illustrated in FIG. 1 with respect to LSFET 120, HSFET 118A and VSFET 118B, respectively. Also, the 2DEG 114 may be established in the channel layer 112 outside the gate region of each of the corresponding GaN FET, e.g., depicted as 2DEG segments 114A, 114B, in respective access regions. In some versions of the examples herein, the source region of a GaN FET (where a source electrode or contact is formed) and the drain region (where a drain electrode or contact is formed) may be asymmetrically disposed relative to the gate region of the GaN FET although it is not a requirement. For example, there may be a greater lateral distance between the gate region and the drain region of a GaN FET than a lateral distance between the gate region and the source region of the GaN FET device.

To effectuate electrical isolation between a high voltage side and a low voltage side of the semiconductor device 100, the isolation region 138A between the first area 199A including LSFET 120 and the second area 199B including HSFET 118A is provided as an isolation region having a sufficient depth vertically extending through the conductive layer 106 and into the lower III-N stack 104. On the other hand, both HSFET 118A and VSFET 118B are provided as high side devices appropriately connected together for selectively driving VSFET 118B as will be set forth below. Accordingly, the isolation region 138B between the second area 199B including HSFET 118A and the third area 199C including VSFET 118B is provided as an isolation region that extends through the upper III-N stack 107 only partially, e.g., without reaching or extending through the conductive layer 106 but stopping in the upper III-N stack 107 at a suitable depth. In some versions, the isolation region 138B may extend into and stop in the upper buffer layer 110 of the upper III-N stack 107. In some versions, the isolation region 138B may extend into and stop in the channel layer 112 of the upper III-N stack 107.

Isolation regions 138A and 138B may be formed by a suitable process, e.g., trench isolation, implantation, etc. Further, the isolation regions 138A and 138B may be formed before patterning the p-GaN layer or after patterning the p-GaN layer of the semiconductor device 100. Moreover, the isolation regions 138A and 138B may be formed in a single step process or a multi-step process. Furthermore, the isolation regions 138A and 138B may be formed in the semiconductor device 100 in any order or sequence within a process flow according to some example arrangements. For example, a shallow isolation region 138B may be formed first followed by the formation of a deeper isolation region 138A in some implementations.

In an example arrangement including isolation implantation, a photolithography step may be used to cover the active areas of GaN FETs leaving the isolation regions 138A and 138B exposed to an isolation implant. In some implementations, the isolation implant may include an implant of argon, silicon, fluorine, or nitrogen ions implanted with an energy of between 100 kilo-electron volts (keV) and 300 keV with an implant dose of 1×10¹⁴ ions/cm² to 1×10¹⁶ ions/cm². The implanted species cause damage to the crystallinity of the heterojunction structure 105 in the defined areas, e.g., exposed isolation regions 138A, 138B, thus disrupting or disabling the formation of a 2DEG channel in the isolation regions 138A, 138B.

In some process flows including trench isolation, the isolation regions 138A, 138B may be formed using a photolithography step to cover the active areas of GaN FETs leaving the isolation regions 138A, 138B exposed, followed by a plasma etch process. The plasma process may be adapted to remove the barrier layer 116, portions of the upper III-N stack 107 and potions of the lower III-N lower stack 104 (for forming deeper isolation regions 138A), resulting in the formation of suitable trenches in the exposed isolation regions 138A, 138B. A deposition process, e.g., a PECVD processes, may be implemented for filling the trenches with appropriate dielectric materials, e.g., silicon nitride (SiN), silicon dioxide (SiO₂), silicon oxynitride (SiON), etc., where the filled trenches are operable as isolation regions 138A, 138B. Other deposition methods and/or dielectric materials for forming trench isolation are within the scope of the examples herein.

Depending on implementation, source/drain and gate contacts (also referred to as electrodes) may be formed with respect to HSFET 118A, VSFET 118B and LSFET 120 in a gate first flow (e.g., where source/drain contacts are formed after forming a gate stack including a gate contact) or in a gate last flow (e.g., where source/drain contacts are formed before forming a gate stack including a gate contact). As illustrated, a first source contact 136 is formed and disposed in the first source region 150A and a first drain contact 134 is formed and disposed in the first drain region 150C with respect to LSFET 120. A first gate contact 125 of LSFET 120 is formed over the first gate 124 in the first gate region 150B. In similar fashion, a second source contact 128 is formed and disposed in the second source region 152A and a second drain contact 126 is formed and disposed in the second drain region 152C with respect to HSFET 118A. Further, a second gate contact 127 of HSFET 118A is formed over the second gate 122 in the second gate region 152B.

To effectuate half-bridge circuit configuration, the second source contact 128 of HSFET 118A is connected to the first drain contact 134 of LSFET 120 by a suitable conductive path 132A. In some arrangements, the conductive path 132A may be referred to as a first connector. In some arrangements, the first connector or conductive path 132A may be formed as a connecting member of an interconnect level 132 of the semiconductor device 100. Further, a node associated with or coupled to the conductive path 132A may be operable as a switching output node of the half-bridge circuit (not specifically shown in FIG. 1). During operation, the switching output node may be switchably connected to a rail or bus having an input voltage supplied to the high side of the semiconductor device 100. Moreover, the switching output node may be selectively pulled low by virtue of establishing a conductive relationship with the first source contact 136 of LSFET 120, which may be connected to a reference rail or bus having a reference voltage, e.g., a ground. In some examples, the reference voltage may be referred to as a first voltage or a low voltage in relation to the input voltage, which may be referred to as a second volage or a high voltage.

With respect to VSFET 118B, a third source contact 135 is formed and disposed in the third source region 154A and a third drain contact 142 is formed and disposed in the third drain region 154C. VSFET 118B further includes a third gate contact 129 formed over the third gate 123 in the third gate region 154B. In some examples, the third source contact 135 may be formed as a contact electrically coupled to the conductive layer 106. Accordingly, the third source contact 135 may also be referred to as a screen contact or VS contact in some examples. As will be set forth further below, the third source contact 135 may be selectively pulled high during certain phases of operation of the semiconductor device 100.

To facilitate selective driving of the conductive layer 106, e.g., pulling the conductive layer 106 to a high voltage, VSFET 118B is connected to HSFET 118A in the high side portion of the semiconductor device 100 by appropriate conductive paths. As illustrated, the third drain contact 142 of VSFET 118B is connected to the second drain contact 126 of HSFET 118A by a conductive path 132B, which may be referred to as a second connector. Further, the third gate contact 129 VSFET 118B is connected to the second gate contact 127 of HSFET 118A by a conductive path 132C, which may be referred to as a third connector. Similar to the first connector 132A disposed between LSFET 120 and HSFET 118A, the second and third connectors 132B, 132C, respectively, may be formed as corresponding connecting members of an interconnect level, e.g., interconnect level 132, of the semiconductor device 100. Other interconnection schemes for facilitating interconnectivity among or between LSFET 120, HSFET 118A and/or VSFET 118B are within the scope of the present disclosure.

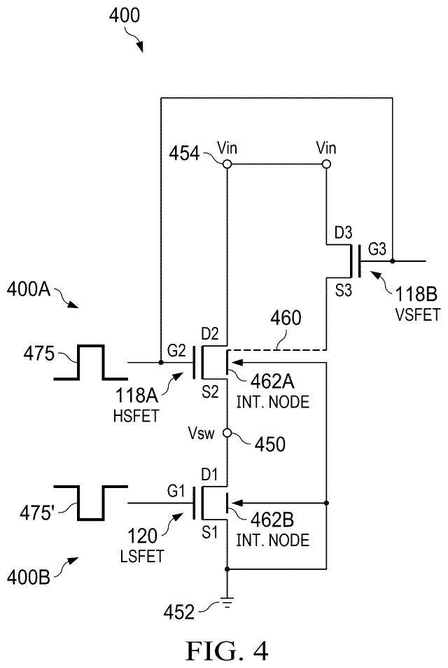

To effectuate half-bridge functionality, the second connector 132B of the semiconductor device 100 commonly connected to the drain contacts 126 and 142 of HSFET 118A and VSFET 118B, respectively, may be coupled to an input node, e.g., as shown in FIG. 4 described below. In some examples, the input node may be operable at a high voltage (voltages ranging from about 200 V to about 800 V or more). Further, the third connector 132C commonly connected to the gate contacts 127, 129 of HSFET 118A and VSFET 118B, respectively, may be operable as a gate control node receiving a gate control signal (e.g., as shown in FIG. 4 described below). In operation, a complementary gate control signal (e.g., having a Boolean logic opposite to the Boolean logic of the gate control signal driving the gates 122, 123) may be provided to the gate 124 of LSFET 120.

In some arrangements, the semiconductor device 100 may include a topside substrate contact (not shown in FIG. 1) to the substrate 102 where a trench contact process may be implemented. For example, a trench extending through the upper and lower III-N stacks 107, 104 and into the substrate 102 may be formed in a substrate contact area using a plasma process. A dielectric liner may be deposited along the interior sidewalls of the trench in order to provide lateral isolation between the substrate contact and the conductive layer 106 while facilitating contact with the substrate 102 at a bottom of the trench. Thereafter, a substrate contact may be formed in the sidewall-isolated trench using suitable metal compositions. In some arrangements, the substrate contact may be commonly connected to a reference voltage node of the low side, e.g., the source contact 136 of LSFET 120.

In some additional and/or alternative arrangements, formation of a substrate contact may be combined with trench isolation, e.g., for forming isolation regions 138A/138B as described above. In some additional and/or alternative arrangements, the semiconductor device 100 may not include a separate contact for the substrate 102. Instead, the substrate 102 may be connected to a reference voltage node by a packaging connection, e.g., using a lead frame, where the reference voltage node may be a ground (GND) rail as noted previously.

In an example fabrication flow, the various layers/sublayers of a III-N stack may be formed over the substrate 102 in successive stages of suitable epitaxial processes. In some arrangements, buffer layers comprising the lower III-N stack 104 may be formed over the substrate 102 by a first metal organic vapor phase epitaxy (MOVPE) process. The first MOVPE process may include delivering an aluminum-containing reagent, such as trimethyl aluminum (TMA) and a nitrogen-containing precursor, such as ammonia (NH₃), in a suitable carrier gas to a reactor containing the substrate 102. The carrier gas may include hydrogen, nitrogen, argon, or any combination thereof. In an example implementation, the first MOVPE process may form a nucleation sublayer of AlN on the substrate 102. The first MOVPE process may subsequently deliver increasing amounts of a gallium-containing precursor, such as trimethyl gallium (TMG) and decreasing amounts of the aluminum-containing precursor, along with the nitrogen-containing precursor, to form one or more transition sublayers of III-N semiconductor material with increasing gallium content on the nucleation sublayer.

In some arrangements, the conductive layer 106 may be formed over the lower III-N stack 104 by a second MOVPE process. The second MOVPE process may deliver the gallium-containing precursor and the nitrogen-containing precursor, along with a dopant-containing precursor, such as silane (SiH₄) or disilane (Si₂H₆) in the carrier gas, to the partially formed semiconductor device 100 including the lower III-N stack 104. The dopant-containing precursors provide n-type dopant silicon (Si) in the conductive layer 106, thus resulting in the conductive layer 106 having n-type conductivity. In an additional and/or alternative version of this example, the dopant-containing precursor may comprise bis(cyclopentadienyl) magnesium II (MgCp2), which provides p-type dopant magnesium (Mg) in the conductive layer 106, so that the conductive layer 106 has p-type conductivity. Other dopant-containing reagents and/or precursors are within the scope of this example.

In some arrangements, a third MOVPE process may be implemented to form at least a portion of the layers/sublayers of the upper III-N stack 107. For example, the upper buffer layer 110 may be optionally formed over the conductive layer 106 by a process that includes delivering a gallium-containing precursor and a nitrogen-containing precursor. In some examples, the channel layer 112 may be formed directly over the conductive layer 106 or over the optional upper buffer layer 110 using a process that includes appropriate reagents/precursors.

Forming the conductive layer 106 using a MOVPE process implemented between the MOVPE processes for forming upper-and lower III-N stacks according to the examples herein may advantageously reduce fabrication cost and complexity of the semiconductor device 100. In some examples, concentration of the dopants in the conductive layer 106 and the thickness 108 of the conductive layer 106 may be adjusted depending on the voltage levels of a power supply application in which the semiconductor device 100 may be deployed. Further, forming the conductive layer 106 using a MOVPE process interposed between other MOVPE processes may advantageously enable use of a commercially more prevalent silicon substrate as the substrate 102, thus eliminating the need for more expensive custom substrates having a conductive layer.

Fabrication of the semiconductor device 100 may continue with forming the barrier layer 116, patterning of p-GaN gates with respect to HSFET 118A, VSFET 118B and LSFET 120 as well as forming the isolation regions 138A/138B as previously noted. Further, various source/drain contacts and gate contacts for HSFET 118A, VSFET 118B and LSFET 120 may be formed in a gate first process or a gate last process as noted above.

In some arrangements, drain contacts 134, 126, 142 and source contacts 136, 128, 135 may include an adhesion layer of titanium or titanium tungsten, and a fill layer of aluminum, by way of example. Depending on implementation, source/drain contact holes for high side devices, e.g., HSFET 118A and VSFET 118B, and low side device, e.g., LSFET 120, may be etched concurrently or separately. In some arrangements, a source contact hole for the source contact 135 of VSFET 118B may be etched through the barrier layer 116, the channel layer 112, and the upper buffer layer 110 (where provided), thus extending to or into the conductive layer 106. On the other hand, a drain contact hole for the drain contact 142 of VSFET 118B may be etched through the barrier layer 116 to make contact with the 2DEG 114. In similar fashion, source/drain contact holes for HSFET 118A and source/drain contact holes for LSFET 120 may be etched through the barrier layer 116 to make contact with the 2DEG 114 in a concurrent process or in separate process loops according to some examples.

In some arrangements, after forming the various source/drain contact holes, an adhesion layer may be formed in the source/drain contact holes (including the screen contact hole for fabricating the third source contact 135 in an example) by a first physical deposition process. Subsequently, a fill layer may be formed on the adhesion layer by a second physical deposition process. The fill layer and the adhesion layer may be patterned using an etch mask and a reactive ion etch (RIE) process to form respective source/drain contacts.

A gate electrode photolithography and etch process may be performed to form gate apertures that expose the p-GaN layer or the patterned gates of LSFET 120, HSFET 118A and VSFET 118B at a suitable process stage depending on whether a gate first process or a gate last process is implemented. Thereafter, respective gate contacts 125, 127, 129 may be formed using metallization processes similar to the source/drain contact processes set forth above. Additional details regarding aspects of gate first and gate last process flows that may be combined in some examples herein may be found in the following U.S. Patent Applications: (i) application Ser. No. 18/756,202, filed on Jun. 27, 2024; and (ii) application Ser. No. 18/788,650, filed on Jul. 30, 2024; each of which is incorporated by reference herein in its entirety for all purposes.

In some additional and/or alternative examples, a virtual substrate layer may be implemented as a second heterojunction structure operable to support at least an additional conductive channel that may provide a screening effect to block (or reduce) the effects of back gating in a semiconductor device. For example, a buried barrier layer having a different bandgap with respect to the upper III-N stack material and/or the lower III-N stack material may be provided for forming a second heterojunction structure operable as a virtual substrate similar to the conductive layer 106 in some implementations.

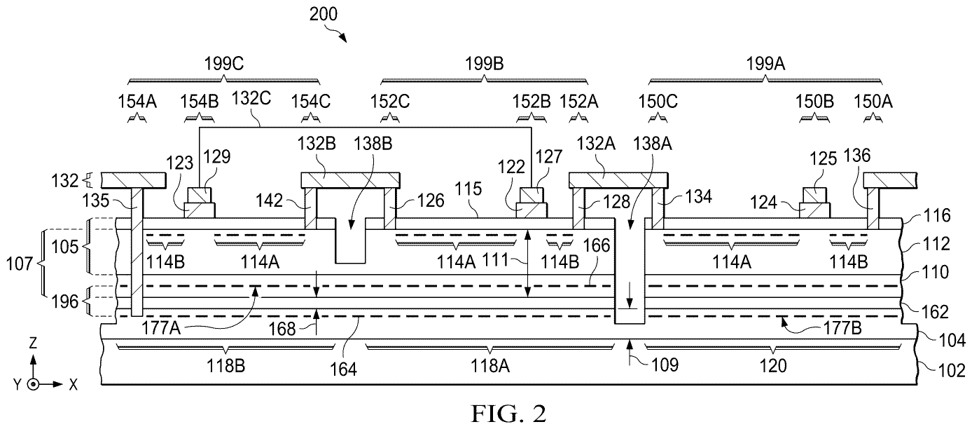

FIG. 2 depicts a cross-sectional view of a semiconductor device 200 according to another example where a barrier layer may be provided for supporting at least a second heterojunction structure operable as a virtual substrate layer to mitigate the effect of back gating. As the functionality of the virtual substrate layer is similar to the functionality of the conductive layer 106, the virtual substrate layer may also be referred to as a conductive layer 196 in the example of FIG. 2. Accordingly, the term “conductive layer” may refer to a doped III-N layer or a second heterojunction structure operable to mitigate the effect of back gating for purposes of the present disclosure.

In the example of FIG. 2, a barrier layer 162 (referred to herein as a “buried barrier layer”) may be formed between the lower III-N stack 104 and the upper III-N stack 107. The buried barrier layer 162 may comprise III-N semiconductor material suitable to establish a second heterojunction structure with one or both of the III-N stacks 104, 107, resulting in the formation of at least an additional conductive channel (e.g., 2DEG and/or 2DHG). Apart from forming the buried barrier layer 162 operable as part of the conductive layer 196, fabrication of the semiconductor device 200 is substantially similar to the fabrication of the semiconductor device 100 as described above. Accordingly, the description and formation of the semiconductor device 100 depicted in FIG. 1 is also applicable to the semiconductor device 200 shown in FIG. 2 except as otherwise noted below.

As illustrated in FIG. 2, the conductive layer 196 includes the buried barrier layer 162 of suitable III-N semiconductor material between the lower buffer layer of the lower III-N stack 104 and the upper buffer layer 110 of the upper III-N stack 107. In an example implementation, the buried barrier layer 162 has a higher bandgap energy than the lower III-N stack 104 underlying the buried barrier layer 162 and has a higher bandgap energy than the upper buffer layer 110 overlying the buried barrier layer 162. The buried barrier layer 162 may include primarily AlN, by way of example. In some examples, the buried barrier layer 162 may comprise a III-N composition similar to that of the barrier layer 116, e.g., AlGaN, InAlGaN, GaN, etc. Other compositions for the buried barrier layer 162 are within the scope of the present disclosure.

The buried barrier layer 162 and the overlying upper buffer layer 110 may form a buried heterojunction structure (e.g., a first buried heterojunction structure) operable as a second heterojunction structure 177A (e.g., relative to the heterojunction structure 105 formed to support device operation, which may be referred to as a first heterojunction structure as noted previously). In this example, the second heterojunction structure 177A is operable to support an upper conductive channel 166, e.g., 2DEG channel, proximate to an interface between the buried barrier layer 162 and the upper buffer layer 110. In similar fashion, the buried barrier layer 162 and the lower III-N stack 104 may form another buried heterojunction structure (e.g., a second buried heterojunction structure) operable as another second heterojunction structure 177B to support a lower conductive channel 164, e.g., 2DEG channel, proximate to an interface between the buried barrier layer 162 and the lower III-N stack 104. For purposes of some examples herein, the first and second buried heterojunction structures 177A, 177B may be cumulatively regarded as a second heterojunction structure forming at least a portion of the conductive layer 196 that includes the upper conductive channel 166, the lower conductive channel 164 and the buried barrier layer 162 disposed therebetween.

In some versions, the buried barrier layer 162 may cause the valence band of the upper buffer layer 110 to cross the Fermi level, producing an upper 2DHG channel 166 rather than a 2DEG channel in the upper buffer layer 110. Accordingly, the reference number 166 in FIG. 2 may refer to either a 2DEG channel or a 2DHG channel depending on implementation of the buried barrier layer 162 and the composition of the upper buffer layer 110. In some versions, neither the conduction band nor the valence band of the upper buffer layer 110 crosses the Fermi level. Accordingly, there may be no upper conductive channel 166 formed as part of the conductive layer 196 in such an arrangement.

The lower conductive channel 164 and the upper conductive channel 166, if formed, are operable to provide free charge carriers in the conductive layer 196. A thickness 168 of the buried barrier layer 162 and a composition of the buried barrier layer 162 may be selected to produce a desired total charge density in the lower conductive channel 164 and the upper conductive channel 166, e.g., similar to the charge density that may be provided in the conductive layer 106 of the semiconductor device 100.

Additional details regarding the formation of conductive layers such as the conductive layers 106 and 196 that may be implemented in the examples herein may be found in U.S. Patent Application Publication No. 2024/0204055, which is incorporated by reference herein in its entirety for all purposes.

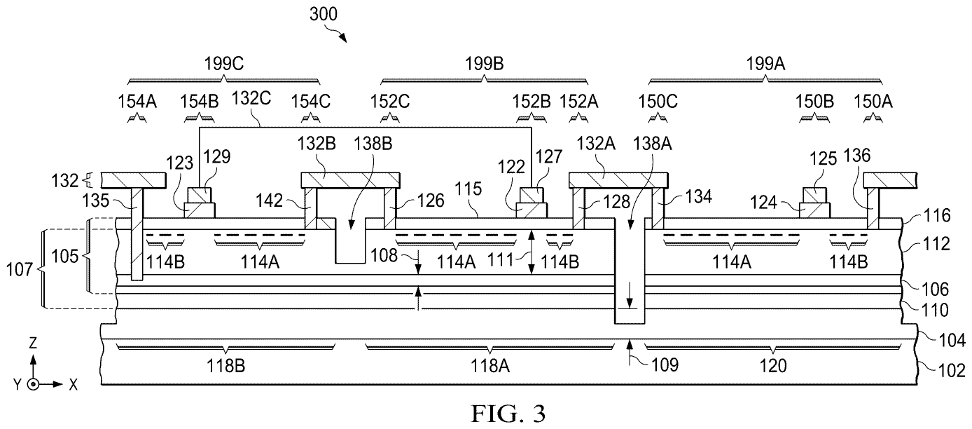

In some additional and/or alternative examples, a conductive layer operable to mitigate the effect of back gating may be provided within a channel layer, e.g., the channel layer 112 (e.g., UID layer 112), instead of being sandwiched between the upper III-N stack 107 and the lower III-N stack 104 as described above. FIG. 3 depicts a cross-sectional view of a semiconductor device 300 according to another example where the conductive layer 106 is formed in the channel layer 112 as a variation of the example shown in FIG. 1. Aside from forming the conductive layer 106 in the channel layer 112 of the upper III-N stack 107, fabrication of the semiconductor device 300 is substantially similar to the fabrication of the semiconductor device 100 as described above. Accordingly, the description and formation of the semiconductor device 100 depicted in FIG. 1 is also applicable to the semiconductor device 300 shown in FIG. 3 except as otherwise noted below.

As previously set forth, the channel layer 112 may comprise a UID III-N layer in some implementations. Because the conductive layer 106 operable as a virtual substrate layer is closer to the surface 115 of the barrier layer 116 than in the examples of FIG. 1 and/or FIG. 2, a shallower screen contact 135 may be provided as a source contact for VSFET 118B in the example of FIG. 3. In similar fashion, the isolation region 138B between VSFET 118B and HSFET 118A may be shallower in the example of FIG. 3 than the isolation region 138B provided in the example of FIGS. 1 and 2. As will be seen below, the location of a conductive layer, e.g., the depth at which the conductive layer is disposed in a III-N stack, may be varied depending on implementation and operational voltages in an application environment.

Because a conductive layer, e.g., conductive layers 106/196, is selectively driven high only during certain phases of operation of a semiconductor device, e.g., semiconductor devices 100, 200, 300, the conductive layer according to the examples herein may be regarded as a “floating” node or a “quasi-floating” node for purposes of the present disclosure. In addition, as the conductive layers 106/196 may be present internally as part of HSFET 118A and LSFET 120 separated by the isolation region 138A, respective portions of the conductive layers 106/196 disposed in the high side and the low side portions of the semiconductor device may represent corresponding internal VS nodes of HSFET 118A and LSFET 120 in a circuit schematic representation of the semiconductor device 100. Furthermore, the conductive layers 106/196 may be absent from the low side portion of the semiconductor device 100 in some examples because there is no back gating effect in the operation of LSFET 120. In such examples, there may be no internal VS node in LSFET 120.

As the conductive layers 106 and 196 are functionally similar, a circuit schematic collectively representing the semiconductor devices 100, 200, 300 is set forth below for purposes of the present disclosure.

FIG. 4 depicts a schematic of a half-bridge circuit 400 representative of the semiconductor devices 100, 200, 300 according to some examples. As depicted, circuit 400 contains a high side portion 400A including HSFET 118A and VSFET 118B and a low side portion 400B including LSFET 120. A drain D1 of LSFET 120 is connected to a source S2 of HSFET 118A at an output node (V_{SW}) 450. A source S1 of LSFET 120 is connected to a reference voltage node 452, e.g., a ground (GND) rail. A drain D2 of HSFET 118A and a drain D3 of VSFET 118B are connected to an input node (V_{IN}) 454 connected to a rail operable at a high voltage. A source S3 of VSFET 118B is internally connected to internal node 462A of HSFET 118A as shown by a dotted path 460. Depending on whether a conductive layer such as the conductive layer 106/196 is formed as part of LSFET 120, LSFET 120 may also include an internal node 462B. Because the internal node 462B is not driven to any particular voltage during operation, the internal node 462B remains floating in some arrangements. Internal nodes 462A and 462B taken together are representative of a conductive layer, e.g., conductive layers 106, 196, that may be segmented between the high side portion 400A and the low side portion 400B due to isolation as described above. Further, respective gates G2 and G3 of HSFET 118A and VSFET 118B are commonly driven by a gate control signal 475. In similar manner, a complementary gate control signal 475′ is operable to drive a gate G1 of LSFET 120.

Taking the semiconductor devices 100/200/300 and the circuit representation 400 together, various phases of device operation according to an example are set forth below.

When LSFET 120 is off (e.g., because the gate control signal 475′ is a logic low) and HSFET 118A and VSFET 118B are on (e.g., because the gate control signal 475 is a logic high), the internal node 462A (e.g., the conductive layer 106/196) connected to the third source contact 135 (e.g., corresponding to S3) of VSFET 118B is driven high. Accordingly, the potential difference between the conductive channel 114 and the conductive layer 106 is insignificant in the high side portion 400A, resulting in minimal or no back gating effect on R_{DSON} performance of HSFET 118A. The upper III-N stack 107 may therefore be formed as a thinner stack of suitable layers, as the need to withstand or block a large potential difference is obviated (or reduced). On the other hand, the large potential difference (|V_{IN}-GND|) between the internal node 462A and the substrate 102 (which may be at ground or GND) may be blocked by the thicker lower III-N stack 104. In an example where the conductive layer 106 is formed within the channel layer 112, e.g., as shown in FIG. 3, the channel layer 112, and hence the upper III-N stack 107, may be provided with sufficient thickness to support the conductive layer 106. Furthermore, the large potential difference (|V_{IN}−GND|) between the internal node 462A and the substrate 102 may be blocked by both the upper buffer layer 110 as well as the buffer layers of the lower III-N stack 104 in this example.

Further, the output node 450 is connected to V_{IN} 454 when LSFET 120 is off and HSFET 118A is on. As the portion of the conductive layer 106/196 in LSFET 120 is electrically isolated from the portion of the conductive layer 106/196 in the high side portion 400A, the internal node 462B may have an indeterminate voltage level (e.g., floating). Accordingly, the internal node 462B may be capacitively coupled between the drain D1 of LSFET 120 and the substrate 102. The large potential difference (|V_{IN}−GND|) between the drain D1 of the LSFET 120 and the substrate 102 may be blocked by the entire thickness of the III-N stack including the upper III-N stack 107, the conductive layer 106 and the lower III-N stack 104 in the low side portion 400B of the half-bridge circuit 400.

When LSFET 120 is on (e.g., because the gate control signal 475′ is a logic high) and HSFET 118A and VSFET 118B are off (e.g., because the gate control signal 475 is a logic low), the internal node 462A is disconnected from V_{IN} 454 and may be floating. In this condition, the internal node 462A may be capacitively coupled between the drains D2 and D3 of the high side portion 400A and the substrate 102. However, the large potential difference (|V_{IN}−GND|) between the drains D2 and D3 of the high side portion 400A and the substrate 102 may be advantageously blocked by the entire thickness of the lower and upper III-N stacks 104, 107 in a similar manner set forth above. As the output node 450 is pulled low (because LSFET 120 is on), the low side portion 400B does not experience a large voltage swing that needs blocking in this phase of operation. In this manner, the half-bridge circuit 400 as implemented in the example semiconductor devices 100, 200, 300 may advantageously mitigate the deleterious effects of back gating without incurring the penalty associated with fabrication of thicker epi stacks.

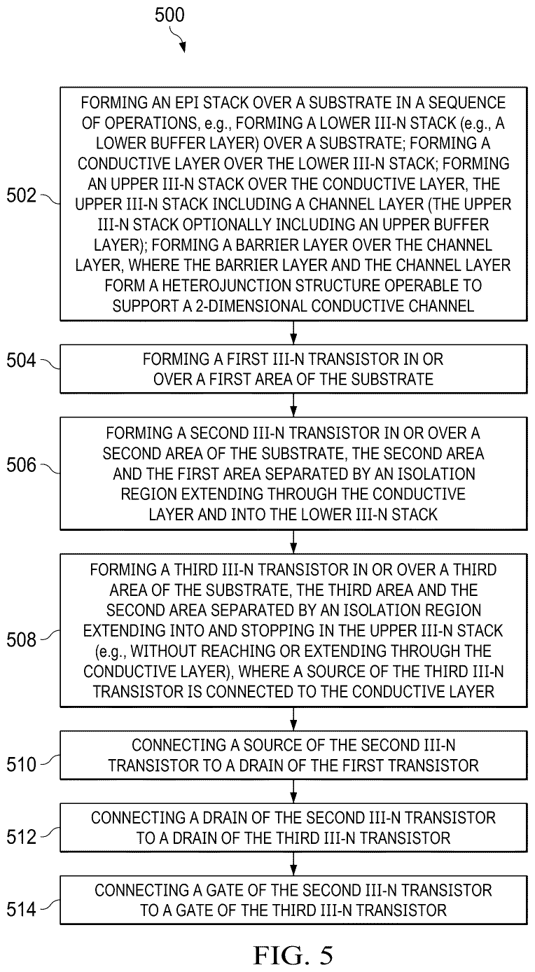

FIG. 5 is a flowchart of a method of fabricating a semiconductor device including GaN devices in monolithic integration according to some examples of the present disclosure. Method 500 may commence with forming an epi stack over a substrate in a sequence of operations or stages as set forth at block 502, e.g., forming a lower III-N stack (e.g., a lower buffer layer) over the substrate; forming a conductive layer over the lower III-N stack; forming an upper III-N stack over the conductive layer, the upper III-N stack including a channel layer (the upper III-N stack optionally including an upper buffer layer); and forming a barrier layer over the channel layer. As noted above, the barrier layer and the channel layer may be operable as a heterojunction structure (e.g., a first heterojunction structure operable to support a 2-dimenional conductive channel (2DEG/2DHG)) for facilitating device operation. Further, the conductive layer may comprise a doped III-N layer or a second heterojunction structure to support additional 2DEG/2DHG channels for providing screening protection against back gating as described above in reference to FIGS. 1-3.

At block 504, a first III-N transistor (e.g., LSFET 120 shown in FIGS. 1-3) is formed in or over a first area of the substrate. At block 506, a second III-N transistor (e.g., HSFET 118A shown in FIGS. 1-3) is formed in or over a second area of the substrate. As noted above, the second area and the first area may be separated by an isolation region extending through the conductive layer and into the lower III-N stack. At block 508, a third III-N transistor (e.g., VSFET 118B shown in FIGS. 1-3) is formed in or over a third area of the substrate. As noted above, the third area and the second area may be separated by an isolation region extending into and stopping in the upper III-N stack, e.g., without reaching the conductive layer. Further, forming the III-N transistor includes forming a screen contact through the upper III-N stack for connecting a source of the third III-N transistor to the conductive layer.

At block 510, a source of the second III-N transistor is connected to a drain of the first III-N transistor, e.g., by a connecting member of an interconnect level of the semiconductor device. At block 512, a drain of the second III-N transistor is connected to a drain of the third III-N transistor, e.g., by a connecting member of an interconnect level of the semiconductor device. At block 514, a gate of the second III-N transistor is connected to a gate of the third III-N transistor, e.g., by a connecting member of an interconnect level of the semiconductor device. Depending on implementation, the various connecting members for interconnecting the first, second and third III-N transistors may comprise a same interconnect level or different interconnect levels of the semiconductor device. As previously noted, the conductive layer may be selectively driven high or left floating to provide screening protection (e.g., voltage blocking capability) using the upper or lower III-N stacks of the semiconductor device during different phases of operation.

Although a monolithic half-bridge circuit implementation comprising EMODE GaN FET devices has been set above in particular detail, the teachings herein may also be applied in a monolithic half-bridge circuit implementation based on DMODE GaN FET devices where a selectively driven VS layer may be provided as a screen layer to mitigate the effects of back gating. In some arrangements, separate gate drive circuitry may be provided to supply a negative voltage to the gates of DMODE devices to allow an “off” state of operation. In some arrangements, the gate drive circuitry to facilitate DMODE functionality may be operable in conjunction with the selective driving of the VS layer using appropriate logic in order to drive the VS layer potential, e.g., close to a high voltage or a rail voltage, during certain phases of operation similar to the functionality set forth above.

While various examples of the present disclosure have been described above, they have been presented by way of example only and not limitation. Numerous changes to the disclosed examples can be made in accordance with the disclosure herein without departing from the spirit or scope of the disclosure. Thus, the breadth and scope of the present disclosure should not be limited by any of the above described examples. Rather, the scope of the disclosure should be defined in accordance with the claims appended hereto and their equivalents.

For example, in this disclosure and the claims that follow, unless stated otherwise and/or specified to the contrary, any one or more of the layers set forth herein can be formed in any number of suitable ways, such as with spin-on techniques, sputtering techniques (e.g., Magnetron and/or ion beam sputtering), (thermal) growth techniques or deposition techniques such as chemical vapor deposition (CVD), physical vapor deposition (PVD), PECVD, or atomic layer deposition (ALD), etc. As another example, silicon nitride may be a silicon-rich silicon nitride or an oxygen-rich silicon nitride. Silicon nitride may contain some oxygen, but not so much that the materials dielectric constant is substantially different from that of high purity silicon nitride.

Further, in at least some additional or alternative implementations, the functions/acts described in the blocks may occur out of the order shown in the flowcharts. For example, two blocks shown in succession may in fact be executed substantially concurrently or the blocks may sometimes be executed in the reverse order, depending upon the functionality/acts involved. Moreover, the functionality of a given block of the flowcharts and/or block diagrams may be separated into multiple blocks and/or the functionality of two or more blocks of the flowcharts and/or block diagrams may be at least partially integrated. Also, some blocks in the flowcharts may be optionally omitted. Furthermore, although some of the diagrams include arrows on communication paths to show a primary direction of communication, it is to be understood that communication may occur in the opposite direction relative to the depicted arrows. Finally, other blocks may be added/inserted between the blocks that are illustrated.

The order or sequence of the acts, steps, functions, components or blocks illustrated in any of the flowcharts and/or block diagrams depicted in the drawing Figures of the present disclosure may be modified, altered, replaced, customized or otherwise rearranged within a particular flowchart or block diagram, including deletion or omission of a particular act, step, function, component or block. Moreover, the acts, steps, functions, components or blocks illustrated in a particular flowchart may be inter-mixed or otherwise inter-arranged or rearranged with the acts, steps, functions, components or blocks illustrated in another flowchart in order to effectuate additional variations, modifications and configurations with respect to one or more processes for purposes of practicing the teachings of the present disclosure. Likewise, although various examples have been set forth herein, not all features of a particular example are necessarily limited thereto and/or required therefor.

At least some portions of the foregoing description may include certain directional terminology, such as, “upper”, “lower”, “top”, “bottom”, “left-hand”, “right-hand”, “front side”, “backside”, “vertical”, “horizontal”, etc., which may be used with reference to the orientation of some of the Figures or illustrative elements thereof being described. Because components of some examples can be positioned in a number of different orientations, the directional terminology is used for purposes of illustration and is in no way limiting. Likewise, references to features referred to as “first”, “second”, etc., are not indicative of any specific order, importance, and the like, and such references may be interchanged, depending on the context, implementation, etc. In addition, terms such as “over”, “under”, “below”, etc., relative to the spatial orientation of two components does not necessarily mean that one component is immediately or directly over the other component, or that one component is immediately or directly under or below the other component. Further, the features and/or components of examples described herein may be combined with each other unless specifically noted otherwise. With respect to terms indicating a relative degree of variation in a value of a parameter or variable, such as, “around”, “about”, “approximately”, etc., such terms may indicate a percentage or fraction of variation in the value of the parameter or variable, e.g., ±5%, ±10%, etc., depending on the context unless otherwise specified.

Although various implementations have been shown and described in detail, the claims are not limited to any particular implementation or example. None of the above Detailed Description should be read as implying that any particular component, element, step, act, or function is essential such that it must be included in the scope of the claims. Where the phrases such as “at least one of A and B” or phrases of similar import are recited or described, such a phrase should be understood to mean “only A, only B, or both A and B.” Reference to an element in the singular is not intended to mean “one and only one” unless explicitly so stated, but rather “one or more.” In similar fashion, phrases such as “a plurality” or “multiple” may mean “one or more” or “at least one”, depending on the context. All structural and functional equivalents to the elements of the above-described implementations are expressly incorporated herein by reference and are intended to be encompassed by the claims appended below.

What is claimed is:

1. A semiconductor device, comprising:
a substrate;
a lower III-N stack over the substrate;
a conductive layer over the lower III-N stack;
an upper III-N stack over the conductive layer, the upper III-N stack including a channel layer;
a barrier layer over the channel layer, the barrier layer and the channel layer forming a first heterojunction structure;
a first III-N transistor disposed over a first area of the substrate, the first III-N transistor including a first source region and a first drain region, wherein a first drain contact is disposed in the first drain region and a first source contact is disposed in the first source region;
a second III-N transistor disposed over a second area of the substrate, the second area laterally separated from the first area by a first isolation region, the second III-N transistor including a second source region and a second drain region, wherein a second drain contact is disposed in the second drain region and a second source contact disposed in the second source region is connected to the first drain contact of the first III-N transistor; and
a third III-N transistor disposed over a third area of the substrate, the third area laterally separated from the second area by a second isolation region, the third III-N transistor including a third source region and a third drain region, wherein a third source contact disposed in the third source region is coupled to the conductive layer and a third drain contact disposed in the third drain region is connected to the second drain contact of the second III-N transistor, and wherein a third gate contact of the third III-N transistor is connected to a second gate contact of the second III-N transistor.

2. The semiconductor device of claim 1, wherein the upper III-N stack comprises an upper buffer layer over the conductive layer, the upper buffer layer including one or more layers of aluminum gallium nitride (AlGaN) with varying aluminum content.

3. The semiconductor device of claim 2, wherein the channel layer is an unintentionally doped (UID) gallium nitride (GaN) layer forming a top portion of the upper buffer layer, the channel layer exclusive of Al contents.

4. The semiconductor device of claim 2, wherein the lower III-N stack comprises a lower buffer layer including one or more layers of aluminum gallium nitride (AlGaN) with varying aluminum content.

5. The semiconductor device of claim 1, wherein the first isolation region extends through the conductive layer and into the lower III-N stack.

6. The semiconductor device of claim 1, wherein the second isolation region extends through the barrier layer and into the upper III-N stack without reaching the conductive layer.

7. The semiconductor device of claim 1, wherein the conductive layer comprises a doped III-N layer.

8. The semiconductor device of claim 7, wherein the doped III-N layer is doped with p-type dopants or n-type dopants.

9. The semiconductor device of claim 1, wherein the conductive layer comprises a second heterojunction structure including a 2-dimensional conductive channel.

10. The semiconductor device of claim 9, wherein the second heterojunction structure includes a gallium nitride (GaN) layer, an aluminum nitride (AlN) layer, an aluminum gallium nitride (AlGaN) layer and/or an indium AlGaN (InAlGaN) layer.

11. A semiconductor device, comprising:
a first III-N field effect transistor (FET) including a first gate, the first III-N FET disposed between an output node and a reference voltage node;
a second III-N FET including a second gate, the second III-N FET disposed between an input voltage node and the output node; and
a third III-N FET including a third gate connected to the second gate, the third III-N FET disposed between the input voltage node and a node internal to the second III-N FET.

12. The semiconductor device of claim 11, wherein the first, the second and the third III-N FETs each comprise an enhancement mode (EMODE) GaN transistor.

13. The semiconductor device of claim 11, wherein the first III-N FET includes a node internal to the first III-N FET, and wherein the node internal to the first III-N FET corresponds to a conductive layer disposed between an upper III-N stack and a lower III-N stack of the first III-N FET.

14. The semiconductor device of claim 11, wherein a source of the third III-N FET is connected to the node internal to the second III-N FET.

15. The semiconductor device of claim 11, wherein the node internal to the second III-N FET corresponds to a conductive layer disposed between an upper III-N stack and a lower III-N stack of the second III-N FET.

16. The semiconductor device of claim 11, wherein the node internal to the second III-N FET is a doped conductive layer disposed in an unintentionally doped (UID) gallium nitride (GaN) layer forming a channel layer of the second III-N FET.

17. The semiconductor device of claim 11, wherein the node internal to the second III-N FET is a heterojunction structure disposed between an upper III-N stack and a lower III-N stack of the second III-N FET.

18. A method, comprising:
forming a lower III-N stack over a substrate;
forming a conductive layer over the lower III-N stack;
forming an upper III-N stack over the conductive layer, the upper III-N stack including a channel layer;
forming a barrier layer over the channel layer, the barrier layer and the channel layer forming a first heterojunction structure;
forming a first III-N transistor in or over a first area of the substrate;
forming a second III-N transistor in or over a second area of the substrate;
forming a third III-N transistor in or over a third area of the substrate, wherein a source of the third III-N transistor is connected to the conductive layer;
connecting a source of the second III-N transistor to a drain of the first III-N transistor;
connecting a drain of the second III-N transistor to a drain of the third III-N transistor; and
connecting a gate of the second III-N transistor to a gate of the third III-N transistor.

19. The method of claim 18, further comprising:
forming a first isolation region between the first and second areas.

20. The method of claim 19, wherein the first isolation region extends through the conductive layer and into the lower III-N stack.

21. The method of claim 19, further comprising:
forming a second isolation region between the third and second areas.

22. The method of claim 21, wherein the second isolation region extends through the barrier layer and into the upper III-N stack without reaching the conductive layer.
